(19) United States
(12) Patent Application Publication
(10) Pub. No.: US 2016/0360609 A1
(43) Pub. Date: Dec. 8, 2016

(54) CIRCUIT SUBSTRATE AND ELECTRONIC EQUIPMENT INCLUDING THE SAME

(71) Applicant: Samsung Electro-Mechanics Co., Ltd., Suwon-si (KR)

(72) Inventor: Chang-Bo LEE, Suwon-si (KR)

(73) Assignee: Samsung Electro-Mechanics Co., Ltd., Suwon-si (KR)

(21) Appl. No.: 15/077,711

(22) Filed: Mar. 22, 2016

(30) Foreign Application Priority Data
Jun. 8, 2015 (KR) 10-2015-0080434

(51) Int. Cl. H05K 1/02; H05K 1/11

(52) U.S. Cl. CPC H05K 1/0271; H05K 1/0298; H05K 1/115

(57) ABSTRACT

A circuit substrate and an electronic equipment including the same are provided. The circuit substrate includes a build-up layer, a conductive pattern disposed on or within the build-up layer, a conductive via passing through the build-up layer and connected with the conductive pattern, and a dummy groove protruding into or passing through the build-up layer.

### CROSS REFERENCE TO RELATED APPLICATION

This application claims the benefit under 35 USC 119(a) of Korean Patent Application No. 10-2015-0080434 filed on Jun. 8, 2015, in the Korean Intellectual Property Office, the entire disclosure of which is incorporated herein by for all purposes.

### BACKGROUND

1. Field

The following description relates to a circuit substrate and an electronic equipment including the same.

2. Description of Related Art

In producing circuit substrates, a demand exists for developing circuit substrates having finer patterning, thinner sizing, and high functioning. Finer patterning refers to fine line width, pad spacing, alignment strengthening and the like within the circuit substrate. According to the semiconductor fine patterning trends, finer patterns are continuously in demand to produce smaller final products having multi-functional capabilities. Thinner sizing refers to reducing the thickness of a circuit substrate. Producing circuit substrates with thinner sizing allows the production of slimmer electronic equipment. High functioning relates to the ability to embed passive components and/or active components in a circuit substrate to allow the electronic product to perform multiple functions.

Circuit substrates with various structures including coreless substrates are utilized in order to meet the above-mentioned demands. Coreless substrates have a thin thickness and similar electrical performances in comparison with substrates having a core, thus allowing the implementation of fine circuits in electronic products.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a circuit substrate includes a build-up layer, a conductive pattern disposed on or within the build-up layer, a conductive via passing through the build-up layer and connected with the conductive pattern, and a dummy groove protruding into or passing through the build-up layer.

The dummy groove may be configured to disperse a stress generated due to a hardening shrinkage of the build-up layer.

The dummy groove on a surface of the build-up layer may have an elongated shape with a predetermined length.

The dummy groove on the surface of the build-up layer may have a slit shape.

An area of the dummy groove on a surface of the build-up layer may be greater than an area of the conductive via on the surface of the build-up layer.

The dummy groove may be electrically insulated from the conductive pattern.

The dummy groove may be filled with an insulating material.

At least a portion of an inner side surface of the dummy groove may contact the insulating material.

The dummy groove may be filled with a conductive metal.

A bottom surface of the dummy groove may contact the build-up layer.

The general aspect of the circuit substrate may further include a dummy pattern disposed on the build-up layer and connected with the dummy groove filled with the conductive metal.

The build-up layer may include a photoimaging insulating material.

The general aspect of the circuit substrate may further include a groove pad disposed in the build-up layer and connected with the dummy groove.

The groove pad may be in contact with a bottom surface of the dummy groove.

A plurality of dummy grooves may pass through the build-up layer, and at least one of the dummy grooves on a surface of the build-up layer may be arranged to be closer to the conductive via than the conductive pattern.

At least another one of the dummy grooves on the surface of the build-up layer may be arranged to be closer to the conductive pattern than the conductive via.

A plurality of build-up layers, a plurality of conductive patterns, a plurality of conductive vias, and a plurality of dummy grooves may be disposed in the circuit substrate.

The general aspect of the circuit substrate may be a coreless substrate.

In another general aspect, a circuit substrate includes a build-up layer, a conductive pattern disposed on or within the build-up layer, a conductive via passing through the build-up layer and connected with the conductive pattern, and a dummy groove protruding into or passing through the build-up layer and having an elongated shape with a predetermined length on a surface of the build-up layer.

In yet another general aspect, a circuit substrate includes a build-up layer, a conductive pattern disposed on or within the build-up layer, and a dummy groove protruding into or passing through the build-up layer, the dummy groove being filled with an insulating material, and the dummy groove may be electrically insulated from the conductive pattern.

In yet another general aspect, a circuit substrate includes a build-up layer, a conductive pattern disposed on or inside the build-up layer, a dummy groove protruding into or passing through the build-up layer, the dummy groove being filled with a conductive metal, and a dummy pattern disposed on the build-up layer and connected with the dummy groove, and the dummy groove and dummy pattern are electrically insulated from the conductive pattern.

In yet another general aspect, an electronic equipment including a circuit substrate as described above is provided.

Other features and aspects will be apparent from the following detailed description, the drawings, and the claims.

### BRIEF DESCRIPTION OF THE DRAWINGS

FIG. 1 is a perspective view schematically illustrating an electronic equipment in which an example of a circuit substrate is applied.

FIGS. 2A to 2F are sectional views illustrating an example of a method of manufacturing a circuit substrate in which warpage may occur in the circuit substrate.

FIGS. 3A to 3H are sectional views schematically illustrating an example of a method of manufacturing a circuit substrate.

FIGS. 4A to 4D are sectional views schematically illustrating various examples of circuit substrates.

FIGS. 5A to 5C are plan views schematically illustrating examples of surfaces of build-up layers.

FIGS. 6A to 6H are sectional views illustrating another example of a method of manufacturing a circuit substrate.

FIGS. 7A to 7D are sectional views schematically illustrating various examples of circuit substrates.

FIGS. 8A to 8C are plan views schematically illustrating examples of surfaces of build-up layers.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

The terms used in the description are intended to describe certain embodiments only, and shall by no means restrict the present disclosure. Unless clearly used otherwise, expressions in the singular number include a plural meaning. Throughout the description of the present disclosure, terms such as “upper part”, “upper surface”, “lower part” and “lower surface” are represented based on the direction of attached figures so that they may be actually different depending on the direction to which a device is arranged.

Hereinafter, certain embodiments of the present disclosure will be described in detail with reference to the accompanying drawings.

### Electronic Equipment

Circuit substrates may be applied to various electronic devices. For example, a circuit substrate may be found inside a mobile phone, a personal digital assistant, a digital video camera, a digital still camera, a network system, a computer, a monitor, a television, a video game, a smart watch, and other electronic devices well known to one of ordinary skill in the art.

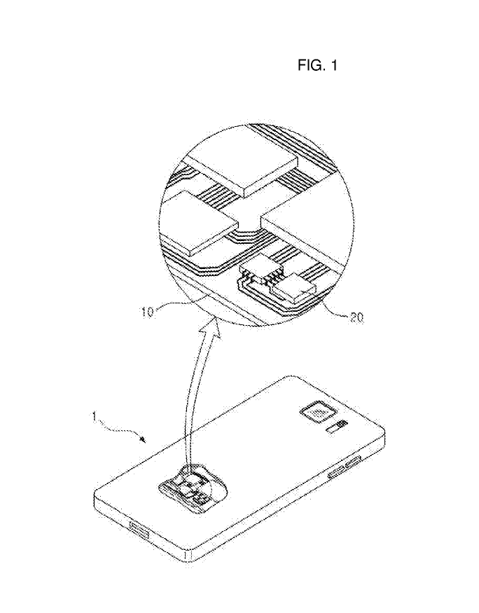

FIG. 1 illustrates an electronic equipment in which an example of a circuit substrate is applied. In this example, the electronic equipment is a mobile device.

Referring to FIG. 1, a circuit substrate according to an example may be used as a main circuit substrate 10 to install or embed various electronic components 20 in an electronic device 1. The circuit substrate 10 may be also used as a base substrate of electronic components 20 such as a semiconductor package that has a smaller size than the circuit substrate 10. Furthermore, it may be applied in various forms to other electronic devices in addition to mobile devices.

### Circuit Substrate

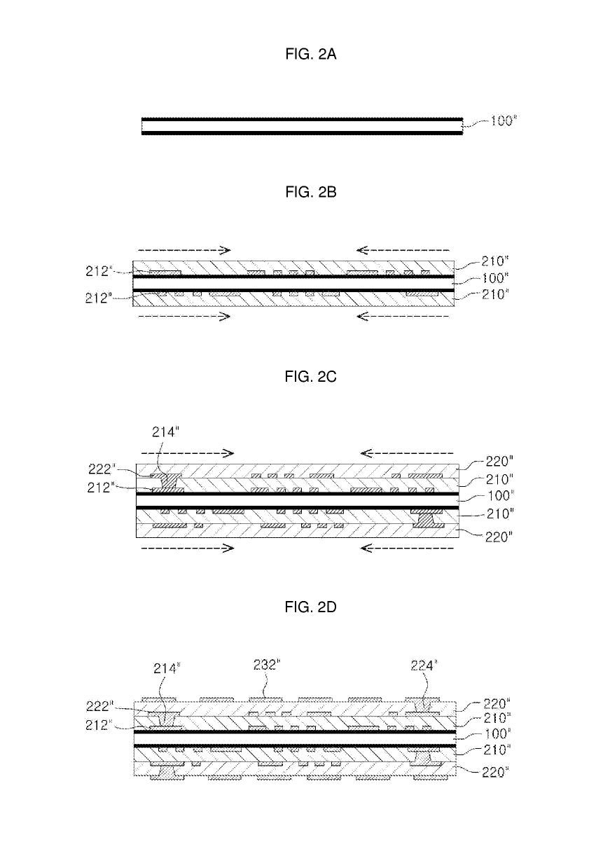

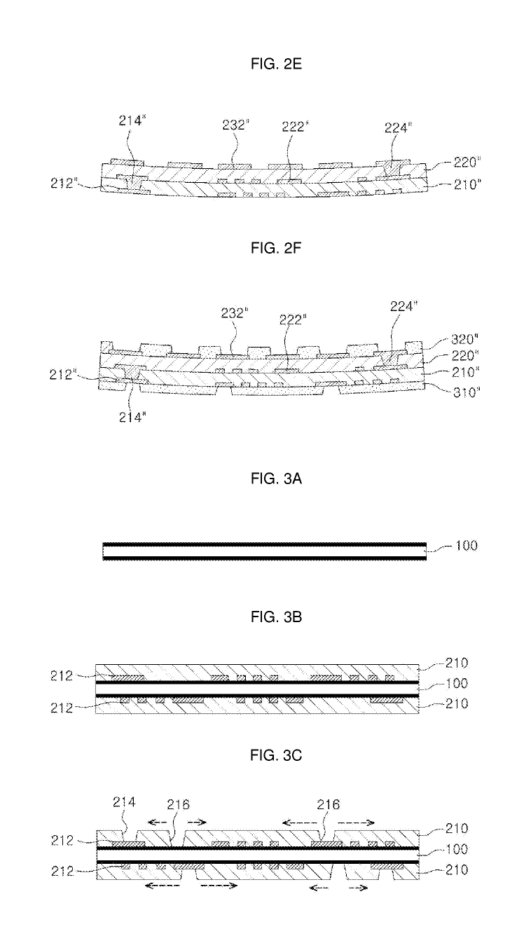

FIGS. 2A to 2F illustrate an example of manufacturing a circuit substrate in which warpage is caused.

Referring to FIGS. 2A to 2F, during the manufacturing process, build-up layers 210″, 220″ formed on a carrier substrate 100″ are hardened. When the hardening of the build-up layers 210″, 220″ occur, a force (arrow) corresponding to a shrinking of the build-up layers 210″, 220″ occurs within the structure. This force remains as a residual stress in each of the build-up layers 210″, 220″ until the circuit substrate is separated from a carrier substrate 100″.

Referring to FIGS. 2E and 2F, when a circuit substrate is separated from the carrier substrate 100″, warpage may occur in the circuit substrate due to residual stress. Furthermore, when the circuit substrate is exposed to severe environmental conditions such as high temperature, warpage may occur in the circuit substrate.

In this example, the circuit substrate includes a dummy groove that passes through at least a part of the build-up layer. This dummy groove may disperse stress, which is generated during hardening shrinkage of the build-up layer during the process for forming the corresponding build-up layer. Thus, the dummy groove may reduce or eliminate warpage of the circuit substrate.

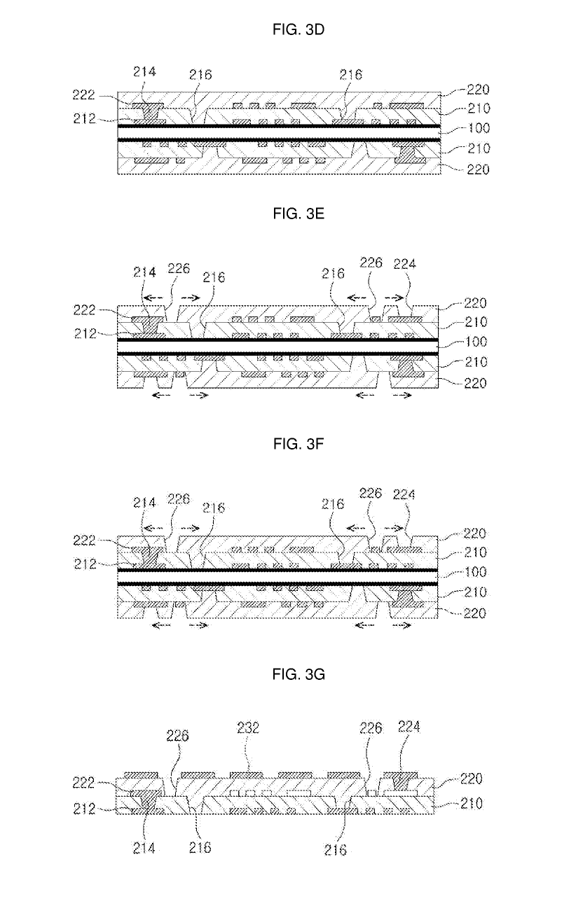

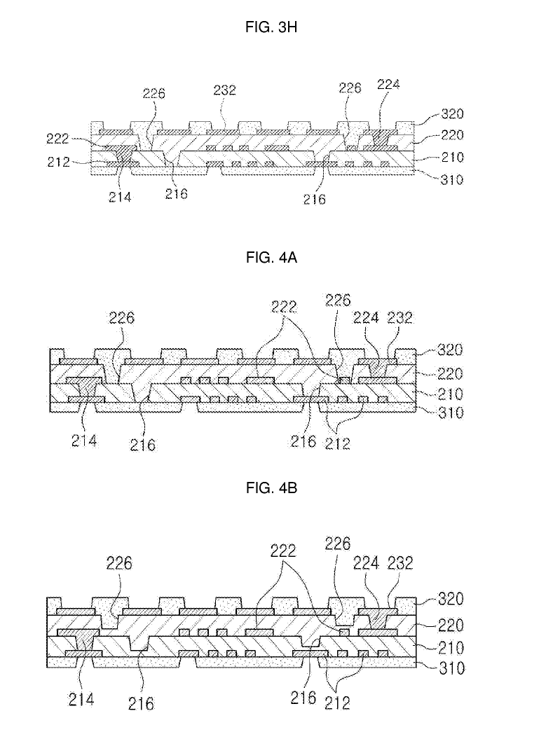

For example, FIGS. 3A to 3H illustrate an example of manufacturing a circuit substrate. Referring to FIGS. 3C and 3E, dummy grooves 216, 226 that protrude into a part of build-up layers 210, 220 or pass through the build-up layers 210, 220, respectively, are formed. When the dummy grooves 216, 226 are formed, stress that is generated in the process of hardening the build-up layers 210, 220, may be distributed (arrow) throughout the build-up layers 210, 220. Referring to FIGS. 3G and 3H, when the build-up layers 210, 220 are separated from the warpage is not occurred in the circuit substrate.

An example in which the dummy grooves 216, 226 protrude into at least a part of the build-up layers 210, 220 in a thickness direction of the build-up layers 210, 220, the dummy grooves 216, 226 may have a tapered shape as illustrated in FIGS. 3G and 3H. However, the shape of the dummy groove 216, 226 is not limited to the illustrated example; variations in shape are within the scope of the present description. The stress that is generated in the process of hardening the build-up layers 210, 220, may be dispersed through various arrangement or shape of the dummy grooves 216, 226 in the build-up layers 210, 220 to improve the warpage of the circuit substrate, in comparison to an example in which the dummy grooves 216, 226 are not formed. Thus, this concept is different from forming vias 214, 224 that pass through the build-up layers 210, 220 to electrically connect with conductive patterns 212, 222, 232. A detailed example will be provided with respect to descriptions below.

In one example, a circuit substrate may be divided into a circuit region on which various patterns 212, 222, 232 are formed, and a dummy region that is eliminated after processing and packaging, which does not remained in a final product. Since the dummy grooves 216, 226 are formed on at least the circuit region, they may be determined in a final product.

FIGS. 3A to 3H illustrate an example of manufacturing a circuit substrate. Even though this example illustrates manufacturing a coreless substrate for convenience, the present description is not limited thereto.

Referring to FIG. 3A, a substrate 100 is prepared. In this example, the substrate 100 to be prepared is a coreless substrate, and the substrate 100 may be a carrier substrate including an insulating plate and at least one metal foil formed on one surface or both surfaces of the insulating plate. On the other hand, in another example, a circuit substrate including a core may be prepared, in which case, the substrate 100 may be a copper clad laminate (CCL).

In the event that the substrate 100 is a carrier substrate, the substrate 100 may include an insulating plate, an inner layer metal foil formed on both surfaces of the insulating plate, and an outer layer metal foil formed on the inner layer metal foil. The inner layer metal foil and the outer layer metal foil may be independently copper foil. However, the inner layer metal foil and the outer layer metal foil are not limited thereto. At least one surface of the interface between the inner layer metal foil and the outer layer metal foil may be surface-treated to facilitate the separation from the substrate 100 later. A release layer may be also formed between the inner layer metal foil and the outer layer metal foil to facilitate the separation from the substrate 100 later.

Referring to FIG. 3B, a first conductive pattern 212 is formed on the substrate 100 and then a first build-up layer 210 is formed to cover the first conductive pattern 212.

The first conductive pattern 212 may be formed through a known process. For example, the first conductive pattern 212 may be formed by a Cu electroplating or an electroless Cu plating using a dry film patter. Examples thereof may include a chemical vapor deposition (CVD), a physical vapor deposition (PVD) such as sputtering, a subtractive process, an additive process using electroless copper plating or copper electroplating, a semi-additive process (SAP) and a modified semi-additive process (MSAP). However, the process is not limited thereto. Even though it is not illustrated, a first groove pad 219 may be formed on the substrate 100, if needed, while the first conductive pattern 212 is formed. The method for forming the first groove pad 219 may be identical to that for forming the first conductive pattern 212.

The first build-up layer 210 may be formed through a known method. For example, it may be formed by compressing an insulating resin in an unhardened film and then hardening the result. The first build-up layer 210 may be also formed by coating with an insulating material for forming the first build-up layer 210 and then hardening the result. The lamination may include performing a hot press that involves pressing for a certain period of time at a high temperature and cooling under the pressure to a room temperature, and cooling the tool under a cold press to separate. The plating may involve a screen printing method that coats with ink using a squeegee, a spray printing method that coats with ink through spray, or the like. The hardening may be drying not to be hardened completely to perform a photolithography process as the following process.

Referring to FIG. 3C, a first dummy groove 216 that passes through the first build-up layer 210 or at least protrudes into a part of the first build-up layer 210 is formed. The first dummy groove 216 may disperse the stress that is generated due to a hardening shrinkage of the first build-up layer 210. A first via hole 214 that passes through the first build-up layer 210 may be also formed. The reference numeral of the via hole is the same as that of a conductive via to be described below.

The first dummy groove 216 and the first via hole 214 may be formed using a mechanical drill and/or a laser drill. Here, the laser drill may be a CO₂ laser or a YAG laser. However, the type of laser drills that may be used is not limited thereto. When a mechanical drill and/or laser drill is used, desmearing may be performed to remove resin smear in the via hole. The desmearing may be performed using permanganate. In an example in which the first build-up layer 210 is a photoimaging insulating layer, the first dummy groove 216 and/or the first via hole 214 may be formed through a photolithography process. Here, when an exposing and developing process is repeated while slowing down a developing speed by controlling a concentration of a developing chemical, the first dummy groove 216 and/or the first via hole 214 with a desired depth may be easily formed.

Referring to FIG. 3D, a second conductive pattern 222 is formed on the first build-up layer 210 and then a second build-up layer 220 is formed to cover the second conductive pattern 222.

The second conductive pattern 222 may be formed through a known process. For example, the second conductive pattern 222 may be formed by a Cu electroplating or an electroless Cu plating using a dry film patter. Examples thereof may include a chemical vapor deposition (CVD), a physical vapor deposition (PVD) such as sputtering, a subtractive process, an additive process using electroless copper plating or copper electroplating, a semi-additive process (SAP) and a modified semi-additive process (MSAP). However, the process is not limited thereto. During the process of forming the second conductive pattern 222, the first via hole 214 may be simultaneously filled with a conductive metal to form the first conductive via 214. Even though it is not illustrated, a second groove pad 229 may be further formed on the first build-up layer 210, if needed, while the second conductive pattern 222 is formed. The method for forming the second groove pad 229 may be identical to that for forming the second conductive pattern 222.

The second build-up layer 220 may be formed through a known method. For example, it may be formed by compressing an insulating resin in an unhardened film using a laminator and then hardening the result. The second build-up layer 220 may be also formed by coating with an insulating material for forming the second build-up layer 220 and then hardening the result. The lamination may include performing a hot press that includes pressing for a certain period of time at a high temperature and cooling under the pressure to a room temperature and cooling the tool under a cold press to separate. The plating may include a screen printing method which coats with ink using a squeegee, a spay printing method which coats with ink through spray, or the like. The hardening may be drying not to be hardened completely to perform a photolithography process as a following process.

While the second build-up layer 220 is formed, the first dummy groove 216 may be filled with the insulating material used for forming the second build-up layer 220. The second dummy groove 226 may be filled with a material used for forming another build-up layer which is to be formed on the second build-up layer 220. When a solder resist layer is formed on the second build-up layer 220 as outer layers 310, 320, it may be filled with the insulating material used for forming the solder resist layer.

Referring to FIG. 3E, a second dummy groove 226 is formed to pass through the second build-up layer 220 or to protrude into the second build-up layer 220. The second dummy groove 226 may disperse the stress that is generated due to a hardening shrinkage of the second build-up layer 220. A second via hole 224 which passes through the second build-up layer 220 may be also formed. The reference numeral of the via hole is the same as that of a conductive via to be described below.

The second dummy groove 226 and the second via hole 224 may be also formed using a mechanical drill and/or a laser drill. In an example in which a photoimaging insulating layer is formed as the second build-up layer 220, the second dummy groove 226 and/or second via hole 224 may be formed through a photolithography process. In an example in which a mechanical drill and/or laser drill is used to form the second dummy groove 226 and the second via hole 224, a desmearing process may be performed to remove resin smear. The desmearing process may be performed using permanganate. In an example in which a photoimaging insulating layer is formed as the second build-up layer 220, the second dummy groove 226 and/or the second via hole 224 may be formed through a photolithography process. In this example, when an exposing and developing process is repeated while slowing down a developing speed by controlling a concentration of a developing chemical, the second dummy groove 226 and/or the second via hole 224 with a desired depth may be easily formed.

Referring to FIG. 3F, a third conductive pattern 232 is formed on the second build-up layer 220. The third conductive pattern 232 may be formed through a known process. For example, the second conductive pattern 222 may be formed by a Cu electroplating or an electroless Cu plating using a dry film patter. Examples thereof may include a chemical vapor deposition (CVD), a physical vapor deposition (PVD) such as sputtering, a subtractive process, an additive process using electroless copper plating or copper electroplating, a semi-additive process (SAP) and a modified semi-additive process (MSAP). However, the process for forming the third conductive pattern 232 is not limited thereto.

In FIG. 3F, a process for manufacturing a circuit substrate, in which the first build-up layer 210 and the second build-up layer 220 are laminated, is illustrated. However, in another example, a further build-up layer may be laminated as desirable through a similar process to the process described above. In yet another example, only one build-up layer may be provided.

Referring to FIG. 3G, when the substrate 100 is a carrier substrate, after forming as many as desired number of build-up layers, the substrate 100 is separated. The substrate 100 may be separated using a blade. The substrate 100 may be separated through a known method. However, the separation method is not limited thereto. For example, the separation of the substrate 100 may involve the separation of the inner layer metal foil and the outer layer metal foil of the substrate 100. In this example, the outer layer metal foil may be eliminated from the circuit substrate in the following process.

Referring to FIG. 3H, after separating the substrate 100, if desirable, outer layers 310, 320 are formed on the upper surface and/or the lower surface of the build-up layer.

The outer layers 310, 320 may be formed by coating the lamination with a material to be used for forming outer layer 310, 320 and the hardening the result. The lamination may include performing a hot press which includes pressing for a certain period of time at a high temperature and cooling under the pressure to a room temperature and cooling the tool under a cold press to separate. The plating may include a screen printing method that coats with ink using a squeegee, a spay printing method which coats with ink through spray, or the like. The hardening may be drying not to be hardened completely to perform a photolithography process as a following process.

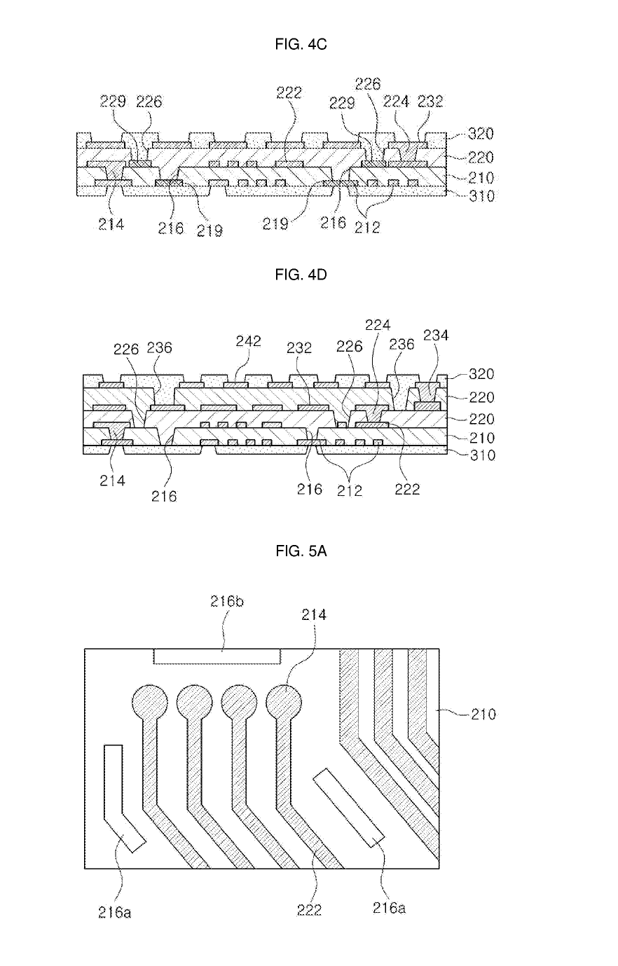

FIGS. 4A to 4D are sectional views schematically illustrating various examples of circuit substrates. These are only examples. The circuit substrate may be prepared through other methods in addition to the illustrated examples.

Referring to FIG. 4A, in this example, a circuit substrate includes build-up layers 210, 220, conductive patterns 212, 222, 232 formed on or inside the build-up layers 210, 220, conductive vias 214, 224 passing through the build-up layers 210, 220, and dummy grooves 216, 226 passing through the build-up layers 210, 220 or protruding into a portion of the build-up layers 210, 220.

The build-up layers 210, 220 may function as an inner insulating layer of the circuit substrate on which a circuit pattern is formed. The build-up layers 210, 220 may be formed of an insulating material. Examples of suitable insulating materials include a thermosetting resin such as an epoxy resin, a thermoplastic resin such as polyimide, or a resin containing a reinforcing agent such as a glass fiber or inorganic filler, such as a prepreg, and the like. An Ajinomoto build-up film may be also used. However, the material is not limited thereto.

The insulating material may be a photoimaging insulating material. In this case, when the dummy grooves 216, 226 and/or the via holes 214, 224 are formed in the build-up layers 210, 220, a photolithography process may be used to control the depth thereof, instead of drilling.

The insulating material may be also a high modulus material. In addition, a material with less hardening shrinkage or an anisotropic material with dominant vertical shrinkage may be also used.

The build-up layers 210, 220 may be formed of the same material or two or more different materials.

The conductive patterns 212, 222, 232 may function as a circuit pattern in a circuit substrate, and be formed of a conductive metal. Examples of the conductive metal may include Cu, Al, Ag, Sn, Au, Ni, Pd and a combination thereof. The conductive patterns 212, 222, 232 may also function as a bump or an electrode when an electronic component is mounted and/or installed in addition to the circuit pattern.

The exposed conductive patterns 212, 222, 232 may be surface-treated as necessary. The surface treatment may be performed through electrolytic gold plating, electroless gold plating, organic solderability preservative or electroless tin plating, electroless silver plating, electroless nickel plating/gold plating substitution, direct immersion gold plating (DIG), hot air solder levelling (HASL) or the like. However, the surface treatment method is not limited thereto.

The conductive vias 214, 224 may electrically connect the conductive patterns 212, 222, 232 with each other which are formed in different layers so that an electrical path may be formed in the circuit substrate. The electrical path may be also connected electrically with electronic components which are to be mounted and/or installed on the circuit substrate. The conductive vias 214, 224 may pass through the build-up layers 210, 220, and be formed of a conductive metal. Examples of suitable conductive metals include Cu, Al, Ag, Sn, Au, Ni, Pd and a combination thereof. However, the materials for forming the conductive vias 214, 224 and the build-up layers 210, 220 are not limited thereto. In another example, other conductive metal or conductors may be used for forming the conductive vias 214, 224 and the build-up layers 210, 220.

Referring to FIGS. 4A to 4D, the conductive vias 214, 224 are fully filled with the conductive metal for convenience. The conductive metal may be filled along the wall of the vias. However, the arrangement is not limited thereto.

In FIGS. 4A to 4D, the conductive vias 214, 224 are independently formed for convenience. However, the configuration of the conductive vias 214, 224 are not limited thereto. In another example, the conductive vias 214, 224 may have a staggered via type in which the conductive vias 214, 224 are arranged to be staggered or a stacked via type in which the conductive vias 214, 224 are arranged to be stacked.

Referring to FIGS. 4A to 4D, the conductive vias 214, 224 are formed in a tapered shape with a decreasing cross-sectional dimension toward the lower surface. However, the shape of the conductive vias 214 is not limited thereto. For example, it may be formed in a tapered shape with an increasing cross-sectional dimension toward the lower surface, in a cylindrical shape, or any shape known in the art.

The dummy grooves 216, 226 may be filled with an insulating material. During the process of filling the dummy grooves 216, 226 with an insulating material, the dummy grooves 216, 226 may be insulated with the conductive patterns 212, 222, 232 even though they are in contact with each other so that freedom in designing circuits may be improved.

At least a part of the inner side of the dummy grooves 216, 226 filled with the insulating material may be in contact with the insulating material. That is, when the dummy grooves 216, 226 are filled with an insulating material, there may be no other material between the inner side of the dummy grooves 216, 226 and the insulating material.

The bottom surface of the dummy grooves 216, 226 filled with the insulating material may be in contact with the bottom surface of the build-up layers 210, 220, or the conductive patterns 212, 222, 232, or both of the bottom surface of the build-up layers 210, 220 and conductive patterns 212, 222, 232.

Referring to FIGS. 4A to 4D, the dummy grooves 216, 226 are fully filled with the insulating material for convenience. However, the configuration of the dummy grooves 216, 226 is not limited thereto. In another example, the dummy grooves 216, 226 may not be fully filled with the insulating material.

Referring to FIGS. 4A to 4D, the dummy grooves 216, 226 are formed in an inverted trapezoidal shape with a decreasing cross-sectional dimension toward the lower surface for convenience. However, the configuration of the dummy grooves 216, 226 is not limited thereto. In another example, a part of the dummy grooves 216, 226 is opened in a thickness direction of the build-up layers 210, 220, or be formed in another shape.

Referring to FIGS. 4A to 4D, the dummy grooves 216, 226 are formed on the build-up layers 210, 220, respectively for convenience. However, the configuration of the dummy grooves 216, 226 is not limited thereto. For example, the dummy grooves 216, 226 may be formed on at least one of the build-up layers 210, 220. However, when dummy grooves 216, 226 are formed on the build-up layers 210, 220, respectively, it provides more effective stress dispersion.

Referring to FIG. 4B, the dummy grooves 216, 226 may completely penetrate through the build-up layers 210, 220, protrude into only a portion of the build-up layers 210, 220, or be in a combination thereof. That is, a depth of the dummy grooves 216, 226 may not be specifically limited, and thus may be any range if it is enough to disperse the stress present in the build-up layers 210, 220.

Referring to FIG. 4C, the circuit substrate according to an example may further include groove pads 219, 229 formed on the build-up layers 210, 220. When the dummy grooves 216, 226 are formed using a laser drill, the dummy grooves 216, 226 may be formed in a desired depth due to the present of the groove pads 219, 229. The groove pads 219, 229 may be in contact with the bottom surface of the dummy grooves 216, 226.

The groove pad may be formed of any material that is used as a conductive material for a circuit in the field. For example, the groove pad may be formed of Cu, Al, Ag, Sn, Au, Ni, Pd or a combination thereof. The exposed groove pad may be surface-treated as necessary. The detail description of the surface treatment is the same as that described above.

Referring to FIGS. 4A to 4D, only two build-up layers 210, 220 are laminated for convenience. However, in another example, three or more build-up layers may be formed if needed. For example, referring to FIG. 4D, three build-up layers 210, 220, 230 may be also formed, and the same description may be applied for each build-up layer.

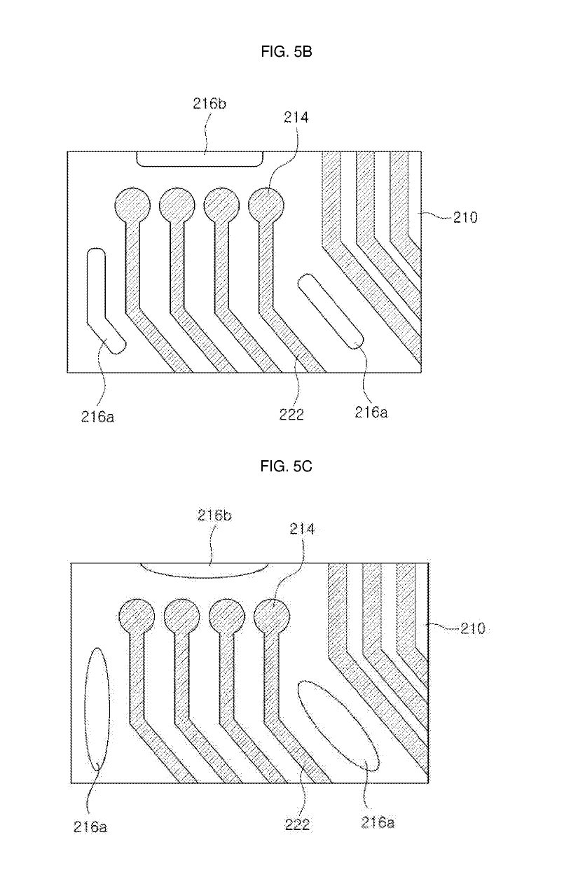

FIGS. 5A to 5C illustrate plan views of examples of build-up layers.

Referring to FIGS. 5A to 5C, the circuit substrate according to an example includes a conductive via 214 on the surface of the build-up layer 210 to be connected with the conductive pattern 222 and the conductive pattern 222, and a dummy groove 216 where the conductive via 214 is not formed.

The dummy groove 216 on the build-up layer 210 may be formed in an elongated shape having a predetermined length. An elongated shape having the predetermined length refers to the fact that a length in a first direction is greater than the dimension in another direction that is perpendicular to the first direction based on the center of the shape. For example, the dummy groove 216 may have a slit shape with a predetermined direction. The stress, which is generated during hardening shrinkage of the build-up layer 210, may occur in various directions on the surface of the build-up layer 210. Thus, the dummy groove 216 may be formed where the conductive pattern 222 and the conductive via 214 are not formed on the surface of the build-up layer 210. When the dummy groove 216 has an elongated shape with a predetermined length, the dispersion of stress may be more effective. Here, the corner of the dummy groove 216 may be any shape, such as, for example, a right angle shape as shown in FIG. 5A, a round shape as shown in FIG. 5B, or an oval shape as shown in FIG. 5C. However, the shape of the corner of the dummy groove 216 is not limited thereto.

The dummy groove 216 on the surface of the build-up layer 210 may have a hole shape such as a circle or a regular polygon, but the dispersion performance for the stress occurred in various directions may be ineffective and arrangement may be more difficult, in comparison to a dummy groove 216 having a slit shape.

An area of the dummy groove 216 on the surface of the build-up layer 210 may be greater than that of the conductive via 214. When the area the dummy groove 216 on the surface of the build-up layer 210 is greater than that of the conductive via 214, the dispersion performance for the stress may be more effective.

At least one dummy groove 216A among the dummy grooves 216 may be arranged to be closer to the conductive pattern 222 than to the conductive via 214. The stress resulting from the shrinkage of the build-up layer 210 during the hardening process may be effectively dispersed by arranging at least one dummy groove 216 near the conductive pattern 222 where the dispersion of stress is otherwise more difficult in comparison to a location near the conductive via 214.

At least one dummy groove 216B among the plurality of dummy grooves 216 may be arranged closer to the conductive via 214 than to the conductive pattern 222. When the dummy grooves 216 are formed over the build-up layer 210, instead of a specific region, the stress that is generated during hardening shrinkage of the build-up layer 210 may be more effectively dispersed through the dummy grooves 216.

In FIGS. 5A to 5C, the dummy grooves 216 are illustrated only on the surface of the first build-up layer 210 for convenience. However, the dummy grooves may be also formed on the surface of the other build-up layer 220 of the circuit substrate.

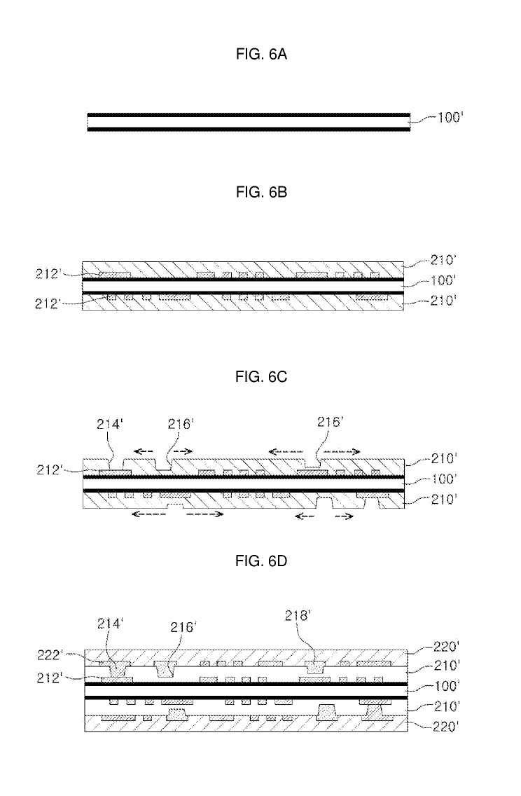

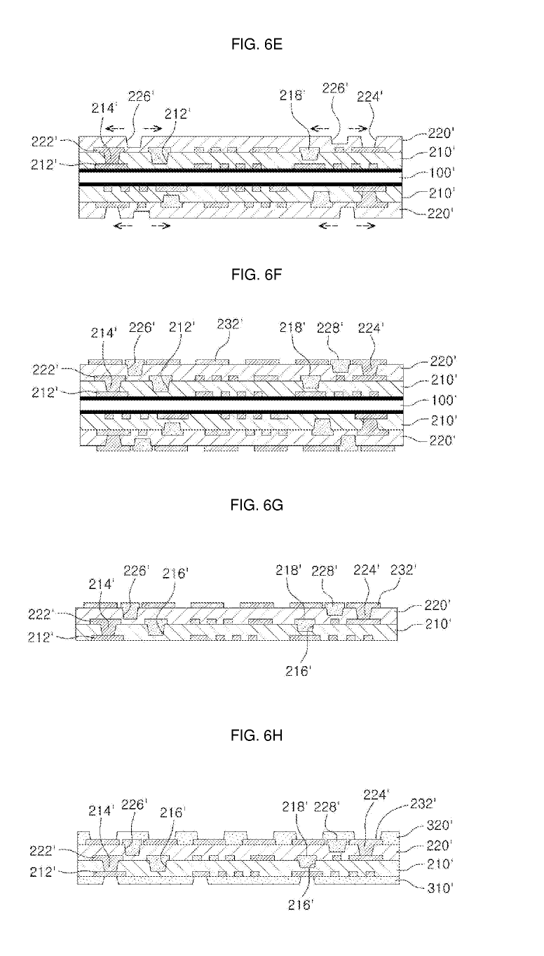

FIGS. 6A to 6H illustrate another example of a method of manufacturing a circuit substrate. Even though FIGS. 6A to 6H illustrate a method of manufacturing a coreless substrate, the present description is not limited thereto. In another example, a circuit substrate with core may be manufactured while applying various illustrated processes.

When describing manufacturing a circuit substrate is determined to be overlapped with the description described above, the pertinent detailed description will be omitted.

Referring to FIG. 6A, a substrate 100′ is prepared. The substrate 100′ may be a carrier substrate or a copper clad laminate. However, the substrate 100′ is not limited thereto.

Referring to FIG. 6B, a first conductive pattern 212′ is formed on the substrate 100′. A first build-up layer 210′ is then formed to cover the first conductive pattern 212′. Even though it is not illustrated, a first groove pad 219′ may be formed on the substrate 100′, if needed, when the first conductive pattern 212′ is formed.

Referring to FIG. 6C, a first dummy groove 216′ is formed to pass through at least a portion of the first build-up layer 210′. The first dummy groove 216′ may be configured to disperse a stress that is generated due to a hardening shrinkage of the first build-up layer 210′. A first via hole 214′ that passes through the first build-up layer 210′ may be also formed while the first dummy groove 216′ is formed.

Referring to FIG. 6D, a second conductive pattern 222′ is formed on the first build-up layer 210′. A first dummy pattern 218′ may be formed on the first build-up layer 210′. A second build-up layer 220′ is formed to cover the first dummy pattern 218′ and the second conductive pattern 222′. Even though it is not illustrated, a second groove pad 229′ may be formed on the first build-up layer 210′, if needed, when the second conductive pattern 222′ is formed.

The first dummy pattern 218′ may be formed through a known method. For example, the dummy pattern 218′ may be formed by a Cu electroplating or an electroless Cu plating using a dry film pattern. Examples thereof include a chemical vapor deposition (CVD), a physical vapor deposition (PVD) such as sputtering, a subtractive process, an additive process using electroless copper plating or copper electroplating, a semi-additive process (SAP), a modified semi-additive process (MSAP) and the like. However, the process is not limited thereto.

During a process for forming the first dummy pattern 218′, the first dummy groove 216′ may be filled with a conductive metal. For example, the first dummy pattern 218′ may be formed to contact the first dummy groove 216′ so that the first dummy groove 216′ may be filled with the same conductive metal that is used for forming the first dummy pattern 218′.

Referring to FIG. 6E, a second dummy groove 226′ is formed to protrude into at least a part of the second build-up layer 220′ or to pass through the second build-up layer 220′. The second dummy groove 226′ may disperse a stress that is generated due to a hardening shrinkage of the second build-up layer 220′. A second via hole 224′ that passes through the second build-up layer 220′ may be also formed.

Referring to FIG. 6F, a third conductive pattern 232′ is formed on the second build-up layer 220′. A second dummy pattern 228′ may be formed on the second build-up layer 220′.

In the process for forming the second dummy pattern 228′, the second dummy groove 226′ may be also filled with a conductive metal. For example, the second dummy pattern 228′ is formed to be in contact with the first dummy groove 216′ so that the second dummy groove 226′ may be filled with the same conductive metal that is used for forming the second dummy pattern 228′.

Referring to FIGS. 6G and 6H, when a substrate 100′ is a carrier substrate, after forming as many build-up layers 210′, 220′ as desirable, the substrate 100′ is separated from the build-up layers 210′, 220′. After separating the substrate 100′, if needed, outer layers 310′, 320′ are formed on the upper surface and/or the lower surface of the build-up layer 210′, 220′.

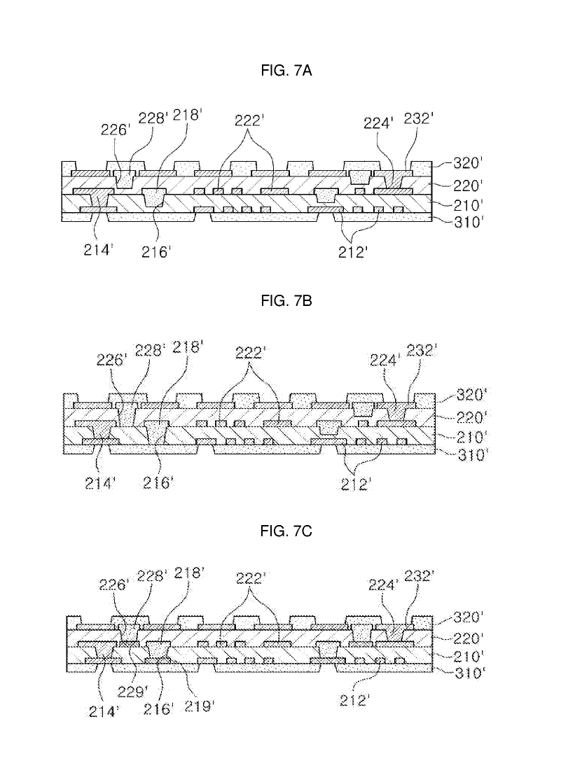

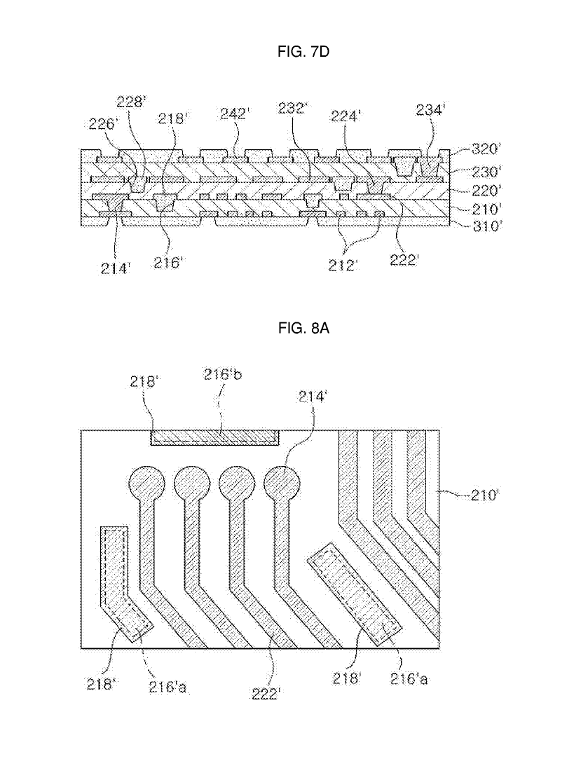

FIGS. 7A to 7D illustrate sectional views of various examples of circuit substrates. The circuit substrate described herein is an example so that it is apparent that the circuit substrate may have a different configuration.

When describing a method for manufacturing a circuit substrate is determined to be overlapped with the description described above, the pertinent detailed description will be omitted.

Referring to FIG. 7A, another example of a circuit substrate includes build-up layer 210′, 220′, conductive pattern 212′, 222′, 232′ formed on or inside the build-up layers 210′, 220′, conductive vias 214′, 224′ passing through the build-up layers 210′, 220′ and connected with the conductive pattern 212′, 222′, 232′, and dummy grooves 216′, 226′ passing through at least a part of the build-up layers 210′, 220′.

The dummy grooves 216′, 226′ may be filled with a conductive metal. When the dummy grooves 216′, 226′ are filled with a conductive metal, stiffness of the build-up layer 210′, 220′ may be improved and further prevent the occurrence of warpage. Examples of the conductive metal may include Cu, Al, Ag, Sn, Au, Ni, Pd and a combination thereof.

The bottom surface of the dummy groove 216′, 226′ filled with the conductive metal may be in contact with the insulating material of the build-up layers 210′, 220′, but may not be in contact with the conductive pattern 212′, 222′, 232′. As a result, the conductive pattern 212′, 222′, 232′ may be electrically insulated.

In this example, the circuit substrate further includes dummy patterns 218′, 228′ on the build-up layers 210′, 220′. The dummy patterns 218′, 228′ may be formed of a conductive metal such as Cu, Al, Ag, Sn, Au, Ni, Pd or a combination thereof. Filling the dummy patterns 218′, 228′ with a conductive metal improves the stiffness of the build-up layers 210′, 220′ and further prevents the occurrence of warpage.

The dummy patterns 218′, 228′ may be in contact with the dummy groove 216′, 226′. The dummy grooves 216′, 226′ may be filled with the conductive metal used for forming the dummy patterns 218′, 228′. That is, the dummy patterns 218′, 228′ and the dummy grooves 216′, 226′ may be integrated. By integrating the dummy patterns 218′, 228′ and the dummy grooves 216′, 226′, the stiffness of the build-up layers 210′, 220′ may be further improved.

Referring to FIG. 7A, the dummy grooves 216′, 226′ are fully filled with the conductive metal for convenience. However, the configuration of the dummy grooves 216′, 226′ is not limited thereto. For example, the conductive metal may fill the dummy grooves 216′, 226′ incompletely.

Referring to FIG. 7A, the dummy patterns 218′, 228′ are formed on the build-up layers 210′, 220′, respectively for convenience. However, the arrangement of the dummy patterns 218′, 228′ is not limited thereto. For example, the dummy patterns 218′, 228′ may be formed on at least one of the build-up layers 210′, 220′. However, when the dummy patterns 218′, 228′ are formed on the build-up layer 210′, 220′, respectively, stress is more effectively dispersed.

Referring to FIG. 7B, the dummy grooves 216′, 226′ filled with the conductive metal pass completely through the build-up layers 210′, 220′, or partially protrudes into the build-up layers 210′, 220′ without completely passing through the build-up layers 210′, 220′. A combination of dummy grooves 216′, 226′ that pass through the build-up layers 210′, 220′ and dummy grooves 216′, 226′ that dummy grooves 216′, 226′ that only partially protrude into the build-up layers 210′, 220′ are found in the illustrated circuit substrate. The dummy grooves 216′, 226′ may be formed not to be in contact with the conductive patterns 212′, 222′, 232′ so that the dummy grooves 216′, 226′ are insulated electrically from the conductive pattern 212′, 222′, 232′.

Referring to FIG. 7C, in another example, the circuit substrate further includes groove pads 219′, 229′ formed in the build-up layers 210′, 220′. When the dummy grooves 216′, 226′ are formed using a laser drill, the dummy grooves 216′, 226′ with a desired depth may be formed due to the groove pads 219′, 229′. That is, the groove pads 219′, 229′ may be formed in contact with the bottom surface of the dummy grooves 216′, 226′.

Referring to FIG. 7C, only two build-up layers 210′, 220′ are laminated for convenience. However, three or more build-up layers 230′ may be formed as desirable. For example, referring to FIG. 7D, three build-up layers 210′, 220′, 230′ may be formed, and the same description may be applied for each build-up layer 210′, 220′, 230′.

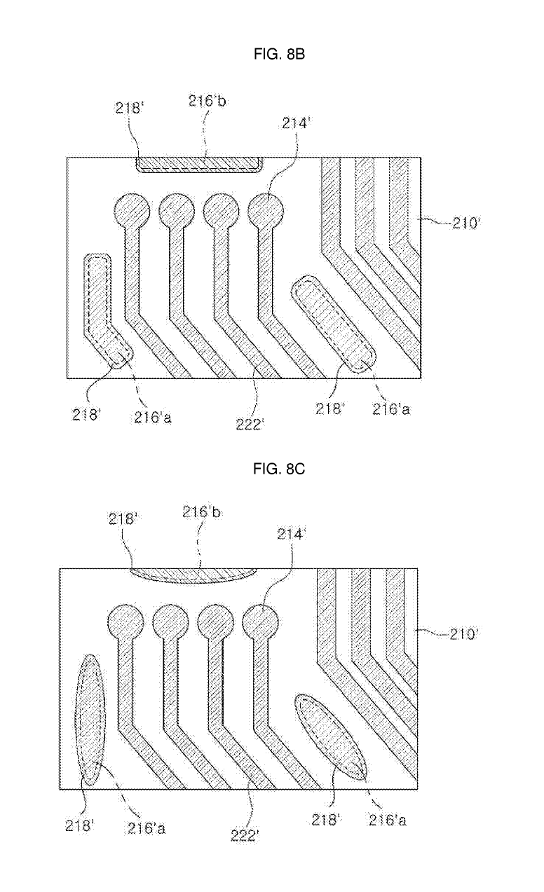

FIGS. 8A to 8C illustrate examples of build-up layer surfaces of circuit substrates in a plan view.

Referring to FIGS. 8A to 8C, a circuit substrate according to another example includes a conductive pattern 222′ formed on a surface of a build-up layer 210′, a conductive via 214′ that is electrically connected with the conductive pattern 222′, and a dummy groove 216′ and a dummy pattern 218′ formed where the conductive pattern 222′ and the conductive via 214′ are not arranged. The dummy groove 216′ and the dummy pattern 218′ are integrated with each other so as to overlap in the plan view of the circuit substrate.

An area of the dummy pattern 218′ on the surface of the build-up layer 210′ may be greater than that of the conductive via 214′ and/or the conductive via pad (not shown). When the area the dummy pattern 218′ on the surface of the build-up layer 210′ is greater than that of the conductive via 214′ and/or the conductive via pad in a plan view of the circuit substrate, the stiffness of the build-up layer 210′ may be more effective.

The shape of the dummy pattern 218′ on the surface of the build-up layer 210′ may vary. Referring to FIGS. 8A to 8C, examples in which the dummy pattern 218′ has an elongated rectangular shape, an elongated rectangular shape with rounded corners, and an elongated oval shape are illustrated as an example. However, these are provided as examples only. In another example, other shapes may be used, provided that the shape is large enough to fully cover the dummy groove 216′ and integrated with the dummy groove 216′ such that the area of the dummy pattern 218′ and the dummy groove 216′ overlap with one another.

Referring to FIGS. 8A to 8C, each dummy pattern 218′ is integrated with each dummy groove 216′ for convenience. However, the arrangement of the dummy pattern 218′ is not limited thereto. For example, the dummy pattern 218′ may be also formed on the surface of the build-up layer 210′ where the conductive pattern 222′ and the conductive via 214′ are not formed by being formed in a plane form so that the dummy pattern 218′ may be integrated with a plurality of dummy grooves 216′.

Referring to FIGS. 8A to 8C, only the surface of the first build-up layer 210′ is illustrated for convenience. However, the same structure may be applied to the other build-up layer 220′ in the circuit substrate.

In a process for manufacturing a thin coreless circuit substrate, warpage may occur in a circuit substrate due to stress generated due to a hardening shrinkage of the build-up layer. According to one example of the present description, a circuit substrate may be provided to prevent such a warpage. According to one example, dummy grooves are provided in a build-up layer to disperse the stress that causes warpage. Thus, the occurrence of warpage may be reduced or eliminated from the circuit substrate.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit substrate comprising:
a build-up layer;
a conductive pattern disposed on or within the build-up layer;
a conductive via passing through the build-up layer and connected with the conductive pattern; and
a dummy groove protruding into or passing through the build-up layer.

2. The circuit substrate of claim 1, wherein the dummy groove is configured to disperse a stress generated due to a hardening shrinkage of the build-up layer.

3. The circuit substrate of claim 1, wherein the dummy groove on a surface of the build-up layer has an elongated shape with a predetermined length.

4. The circuit substrate of claim 3, wherein the dummy groove on the surface of the build-up layer has a slit shape.

5. The circuit substrate of claim 1, wherein an area of the dummy groove on a surface of the build-up layer is greater than an area of the conductive via on the surface of the build-up layer.

6. The circuit substrate of claim 1, wherein the dummy groove is electrically insulated from the conductive pattern.

7. The circuit substrate of claim 6, wherein the dummy groove is filled with an insulating material.

8. The circuit substrate of claim 7, wherein at least a portion of an inner side surface of the dummy groove contacts the insulating material.

9. The circuit substrate of claim 6, wherein the dummy groove is filled with a conductive metal.

10. The circuit substrate of claim 9, wherein a bottom surface of the dummy groove contacts the build-up layer.

11. The circuit substrate of claim 9, further comprising a dummy pattern disposed on the build-up layer and connected with the dummy groove filled with the conductive metal.

12. The circuit substrate of claim 1, wherein the build-up layer comprises a photoimaging insulating material.

13. The circuit substrate of claim 1, further comprising a groove pad disposed in the build-up layer and connected with the dummy groove.

14. The circuit substrate of claim 13, wherein the groove pad is in contact with a bottom surface of the dummy groove.

15. The circuit substrate of claim 1, wherein a plurality of dummy grooves passes through the build-up layer, and at least one of the dummy grooves on a surface of the build-up layer is arranged to be closer to the conductive via than the conductive pattern.

16. The circuit substrate of claim 15, wherein at least another one of the dummy grooves on the surface of the build-up layer is arranged to be closer to the conductive pattern than the conductive via.

17. The circuit substrate of claim 1, wherein a plurality of build-up layers, a plurality of conductive patterns, a plurality of conductive vias, and a plurality of dummy grooves are disposed in the circuit substrate.

18. The circuit substrate of claim 1, wherein the circuit substrate is a coreless substrate.

19. A circuit substrate comprising:
a build-up layer;
a conductive pattern disposed on or within the build-up layer;
a conductive via passing through the build-up layer and connected with the conductive pattern; and
a dummy groove protruding into or passing through the build-up layer and having an elongated shape with a predetermined length on a surface of the build-up layer.

20. A circuit substrate comprising:
a build-up layer;
a conductive pattern disposed on or within the build-up layer; and
a dummy groove protruding into or passing through the build-up layer, the dummy groove being filled with an insulating material;
wherein the dummy groove is electrically insulated from the conductive pattern.

21. A circuit substrate comprising:
a build-up layer;
a conductive pattern disposed on or within the build-up layer;
a dummy groove protruding into or passing through the build-up layer, the dummy groove being filled with a conductive metal; and
a dummy pattern disposed on the build-up layer and connected with the dummy groove,
wherein the dummy groove and dummy pattern are electrically insulated from the conductive pattern.

22. An electronic equipment comprising a circuit substrate of claim 1.
